(19) United States
(12) Patent Application Publication
(10) Pub. No.: US 2014/0035449 A1
(43) Pub. Date: Feb. 6, 2014

(54) ACCESSORY STRAP SECURING MECHANISM

(71) Applicants: FIH (Hong Kong) Limited, Kowloon (HK); SHENZHEN FUTAIHONG PRECISION INDUSTRY CO., LTD., Shenzhen (HK)

(72) Inventors: ZHENG-PING TAN, Shenzhen (CN); YAO WANG, Shenzhen (CN); KUAN-HUNG CHEN, Shindian (TW)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/928,347

(22) Filed: Jun. 26, 2013

(30) Foreign Application Priority Data
Aug. 6, 2012 (CN) 2012102767292

(51) Int. Cl. H05K 5/02

(52) U.S. Cl. CPC H05K 5/023
USPC 312/244; 24/115 R

(57) ABSTRACT

An accessory strap securing mechanism is positioned on a portable electronic device, to assemble an accessory strap thereon. The accessory strap securing mechanism includes a securing portion, a guiding block, and a stopper portion and the securing portion includes a base, a column and an extending end. The column and the extending end extend from the base along two opposite directions and when the front cover and the back cover are separated, the stopper portion is revealed and exposed for an accessory strap to be hooked around the stopper portion. The stopper portion, which is the anchor point of the strap, is enclosed and rendered captive when the front and back covers are clipped together again.

### BACKGROUND

1. Technical Field

The present disclosure relates to an accessory strap securing mechanism for a portable electronic device.

2. Description of Related Art

Portable electronic devices such as mobile phones, MP3s, digital cameras and personal digital assistants are in widespread use, and consumers enjoy the full convenience of high technology products almost anytime and anywhere.

Conventional portable electronic devices usually have an accessory strap securing mechanism disposed thereon to assemble the accessory strap. However, the small size of existing accessory strap securing mechanisms makes it difficult for the accessory strap to be assembled thereto.

Therefore, there is room for improvement within the art.

### BRIEF DESCRIPTION OF THE DRAWING

Many aspects of the present accessory strap securing mechanism in electronic device can be better understood with reference to the following drawings. The components in the various drawings are not necessarily drawn to scale, the emphasis instead being placed upon clearly illustrating the principles of the present accessory strap securing mechanism in electronic device. Moreover, in the drawings, like reference numerals designate corresponding parts throughout the diagrams.

FIG. 1 is an exploded, isometric view of a portable electronic device in accordance with an exemplary embodiment.

FIG. 2 is similar to FIG. 2, but shown from another aspect.

FIG. 3 is an assembled, isometric view of the assembly structure shown in FIG. 1.

FIG. 4 is a cross sectional view of the portable electronic device.

FIG. 5 shows an isometric view of the portable electronic device having an accessory strap assembled therewith.

### DETAILED DESCRIPTION OF THE EMBODIMENT

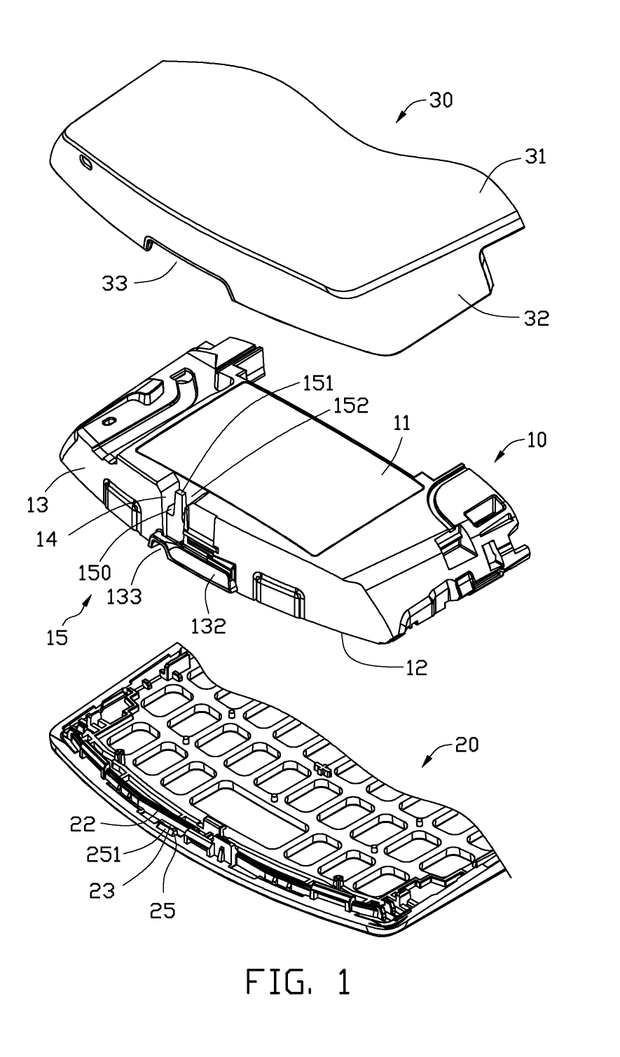

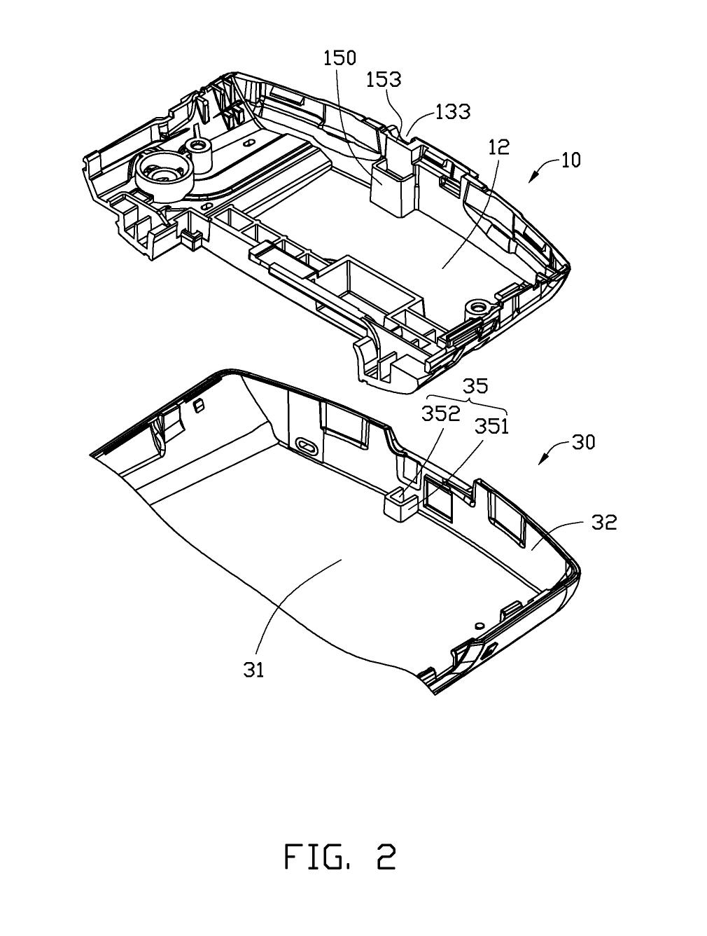

Referring to FIGS. 1 and 2, a portable electronic device comprises a main body 10, a front housing 20, a back housing 30, and an accessory strap securing mechanism disposed thereon, to assemble an accessory strap thereto. The portable electronic device may be a mobile phone, an MP3, a digital camera, a personal digital assistant, or the like. The accessory strap securing mechanism comprises a securing portion 15, a guiding block 25, and a stopper portion 35.

In the exemplary embodiment, the main body 10 comprises a first surface 11, a second surface 12, and an end wall 13 connecting the first surface 11 and the second surface 12. The end wall 13 defines a through hole 14 communicating with the first surface 11 and the second surface 12. The securing portion 15 is located in the through hole 14 and comprises a base 150, a column 151 and an extending end 153. The base 150 extends from opposite inner surfaces of the through hole 14. The column 151 and the extending end 153 extend from the base 150 along two opposite directions. The column 151 is spaced from the inner surface of the through hole 14 to define a receiving groove 152. A latching plate 132 is formed on the end wall 13. The latching plate 132 defines a strap hole 133 communicating with the through hole 14.

The front housing 20 is latched with the second surface 12 of the main body 10. A limiting plate 22 is formed at one end of the front housing 20. The guiding block 25 is formed at one end of the front housing 20, and is spaced from the limiting plate 22. A latching groove 23 is defined between the guiding block 25 and the limiting plate 22 for latching the extending end 153. The guiding block 25 has a guiding sloping surface 251 for guiding the accessory strap.

The back housing 30 comprises a main plate 31 and a peripheral wall 32. A cutout 33 is defined in the peripheral wall 32. The stopper portion 35 is formed on the main plate 31 and is connected to the peripheral wall 32. The stopper portion 35 is substantially U-shaped and comprises a U-shape frame 351 and a slot 352 surrounded by the U-shaped frame 351. When the back housing 30 is engaged with the main body 10, the frame 351 is received in the through hole 14. The column 151 is latched in the slot 352.

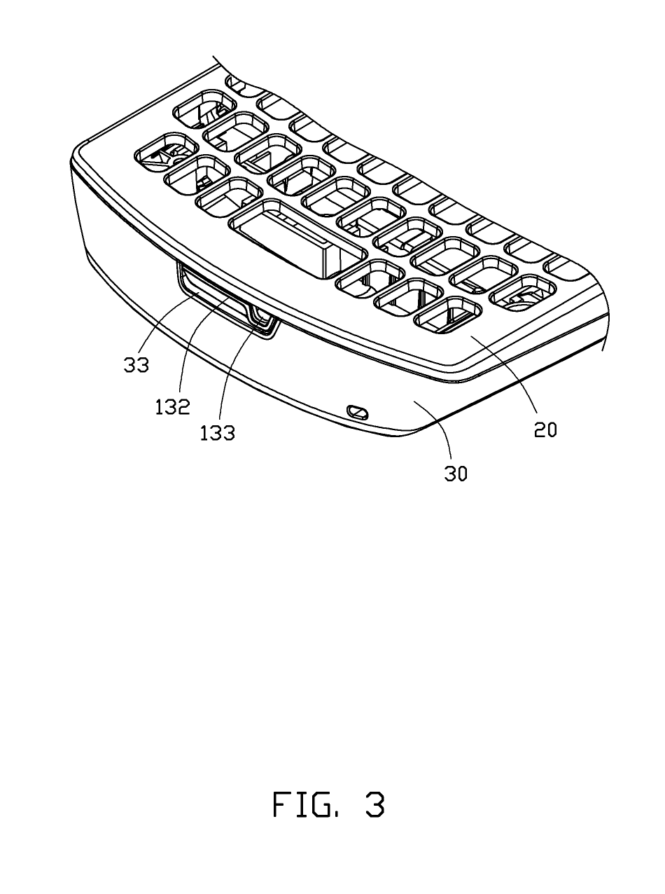

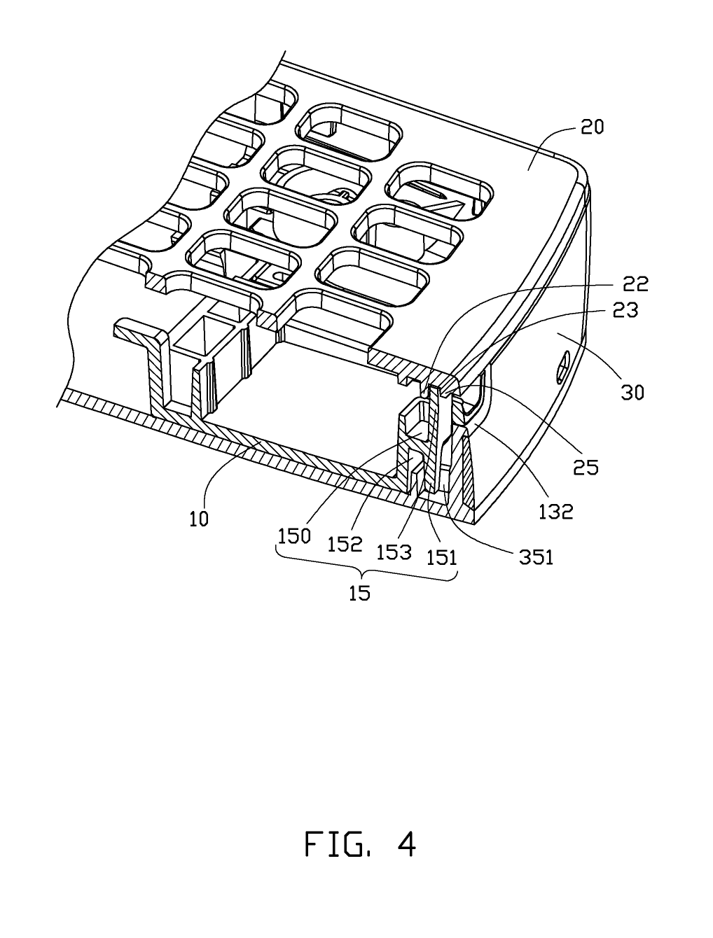

Referring to FIGS. 3 and 4, during assembly of the accessory strap securing mechanism, firstly, the front housing 20 is positioned on the second surface 12 of the main body 10. The guiding block 25 is aligned with the strap hole 133. The extending end 153 is latched in the latching groove 23. Then, the back housing 30 is positioned on the first surface 11 of the main body 10. The latching plate 132 is received in the cutout 33, and the strap hole 133 communicates with the cutout 33. The frame 351 is thus received in the receiving groove 152.

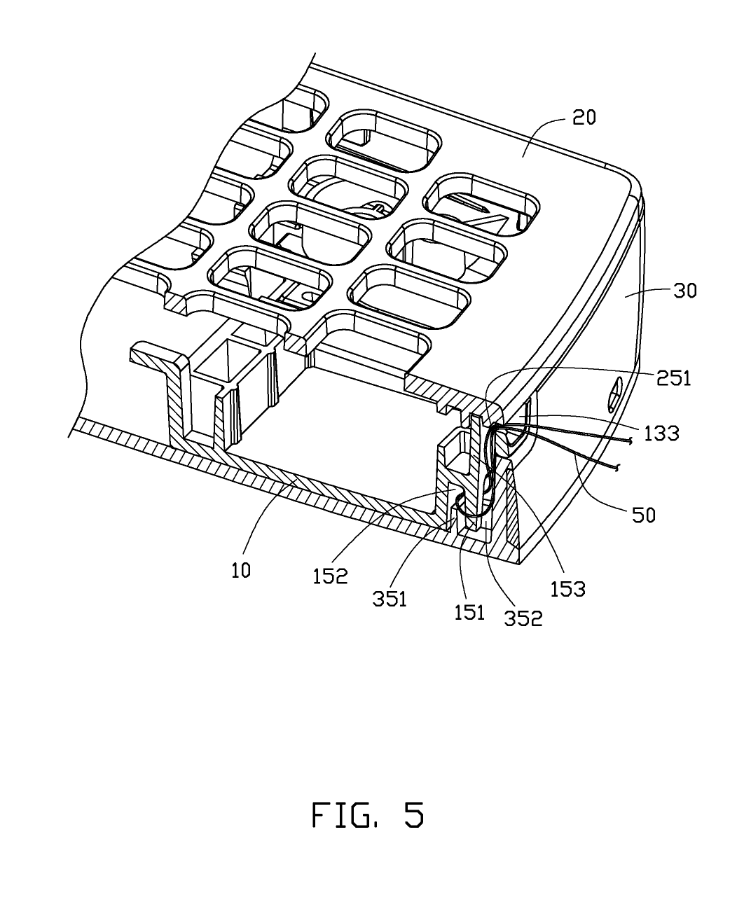

Referring to FIG. 5, when assembling the accessory strap 50, the back housing 30 is detached from the main body 10 and the column 151 is exposed from the main body 10. The accessory strap 50 is inserted inside of the main body 10 through the strap hole 133 and is guided by the guiding sloping surface 251 until the accessory strap 50 fits around the column 151. Finally, the back housing 30 is engaged with the main body 10 and the column 151 latched in the slot 352 of the frame 351 for preventing the accessory strap 50 from separating from the portable electronic device. Thus, the accessory strap 50 is attached to the portable electronic device. It is easy to operate and assemble the accessory strap 50 quickly and conveniently.

It is to be understood that even though numerous characteristics and advantages of the present embodiments have been set forth in the foregoing description, together with details of structures and functions of various embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An accessory strap securing mechanism comprising:
a securing portion comprising a base, a column, and an extending end; the column and the extending end respectively extend from the base along two opposite directions;
and the column is configured for holding the accessory strap;
a guiding block engaging with the extending end; and
a stopper portion engaging with the column and preventing the accessory strap from separating from the column.

2. The accessory strap securing mechanism as claimed in claim 1, wherein the stopper portion comprises a U-shaped frame and a slot surrounding by the U-shaped frame, and the column is latched in the slot.

3. The accessory strap securing mechanism as claimed in claim 2, wherein a limiting plate is spaced from the guiding block, a latching groove is defined between the guiding block and the limiting plate, and the extending end is latched in the latching groove.

4. The accessory strap securing mechanism as claimed in claim 1, wherein the guiding block has a guiding sloping surface for guiding the accessory strap.

5. A portable electronic device comprising:
a main body;
a front housing positioned at a first side of the main body;
a back housing positioned at a second side of the main body; and
an accessory strap securing mechanism comprising:
a securing portion formed on the main body, the securing portion comprising a base, a column, and an extending end; the column and the extending end respectively extend from the base along two opposite directions; the column is configured for holding an accessory strap;
a guiding block formed on the front housing and engaging with the extending end; and
a stopper portion formed on the back housing and engaging with the column and preventing the accessory strap from separating from the column.

6. The portable electronic device as claimed in claim 5, wherein the main body comprises an end wall, the end wall defines a through hole and has a latching plate, the securing portion is formed in the through hole, and the latching plate defines a strap hole communicating with the through hole.

7. The portable electronic device as claimed in claim 5, wherein the front housing has a limiting plate at one end, the guiding block is formed at one end of the front housing, and is spaced from the limiting plate.

8. The portable electronic device as claimed in claim 7, wherein a latching groove is defined between the guiding block and the limiting plate for latching the extending end.

9. The portable electronic device as claimed in claim 5, wherein the back housing includes a main plate and a peripheral wall, the peripheral wall defines a cutout, the stopper portion is formed on the main plate, and is connected to the peripheral wall.

10. The portable electronic device as claimed in claim 9, wherein the stopper portion includes a U-shaped frame and a slot surrounding by the U-shaped frame, and the column is latched in the slot.
